(19) United States
(12) Patent Application Publication
(10) Pub. No.: US 2022/0321078 A1
(43) Pub. Date: Oct. 6, 2022

(54) SOLID REFLECTION-TYPE BULK ACOUSTIC RESONATOR AND PREPARATION METHOD THEREOF

(71) Applicant: University of Electronic Science and Technology of China, Chengdu, Sichuan (CN)

(72) Inventors: Yao SHUAI, Chengdu, Sichuan (CN); Chuangui WU, Chengdu, Sichuan (CN); Wenbo LUO, Chengdu, Sichuan (CN)

(21) Appl. No.: 17/608,744

(22) PCT Filed: Nov. 13, 2019
(86) PCT No.: PCT/CN2019/118087

§ 371 Date: Nov. 3, 2021

(30) Foreign Application Priority Data
May 13, 2019 (CN) 201910393000.5

(51) Int. Cl. H03H 3/02; H03H 9/02; H03H 9/17

(52) U.S. Cl. CPC H03H 3/02; H03H 9/02015; H03H 9/0211; H03H 9/174; H03H 2003/023

(57) ABSTRACT

The present invention provides a preparation method of solid reflection-type bulk acoustic resonator, including the following steps: taking a piece of ion-implanted piezoelectric material, growing reflecting layers below the implantation face of the piezoelectric material and/or above the substrate, then taking a substrate, and bonding it to the piezoelectric material; heating the bonded intermediate product gained to strip the film from the piezoelectric material and growing an upper electrode on the stripped side of the piezoelectric material. According to the preparation method of solid reflection-type bulk acoustic resonator disclosed in the present invention, resonators with high strength and good performance can be prepared by using wafer bonding and lay transfer technique for preparing high-quality piezoelectric films and combining the solid reflecting layer structure.

### FIELD OF THE INVENTION

The present invention belongs to the field of single-crystal thin-film device processing, and specifically, it relates to a solid reflection-type bulk acoustic resonator and preparation method thereof.

### BACKGROUND OF THE INVENTION

Due to the small volume and high quality factor (Q value), film bulk acoustic resonators (FBARs) have been widely used in the field of wireless communication. FBARs, by virtue of the inverse piezoelectric effect of the piezoelectric film, convert electrical energy into sound waves to form resonance. Their resonant cavity is of a sandwich structure with the piezoelectric film as the support between two metal electrodes, and their resonance frequency, also affected by the features and thickness of other elements of the sandwich structure, is mainly inversely proportional to the thickness of the piezoelectric film. To obtain a resonator with high Q value, the resonance energy must be confined within the piezoelectric layer. In an ideal total reflection state, two sides of the resonant cavity of the sandwich structure are surrounded by air, while with this structure, the resonance zone is suspended in the air, leading to poor mechanical strength. However, the solid reflection-type bulk acoustic resonator, with multiple reflecting layers prepared in the resonance zone and below, can effectively reflect the resonance energy, showing apparent advantages in structural strength.

By the current preparation methods, the solid reflection-type bulk acoustic resonator is mainly fabricated by first depositing reflecting layer, lower electrode and piezoelectric layer on the substrate and then preparing upper electrode. For example, the temperature compensated film bulk acoustic resonator and preparation method thereof disclosed in Chinese Patent Literature CN101958696A. According to this method, aluminum nitride films are mainly used as piezoelectric films and electron beam deposition is applied, making it hard to ensure the proper lattice orientation; moreover, the deposition is conducted on metal electrodes and the film uniformity is affected by the electrode layer, thus adversely affecting the film quality and the resonance frequency due to the generation of multiple harmonic waves by the device; the aluminum nitride film has a relatively low electromechanical coupling coefficient, making it hard to satisfy the requirement of broad band filtering.

### SUMMARY OF THE INVENTION

The present invention provides a preparation method of solid reflection-type bulk acoustic resonator to solve the problems existing in the current techniques for preparing the solid reflection-type bulk acoustic resonator, such as difficulty in ensuring the proper lattice orientation, poor film quality, huge impact on resonance frequency due to the generation of multiple harmonic waves by the device and difficulty in satisfying the requirement of broad band filtering.

To solve the abovementioned problems, the present invention provides a preparation method of solid reflection-type bulk acoustic resonator, comprising the following steps:

(a) Taking a piece of ion-implanted piezoelectric material, and growing reflecting layers below the implantation face of the said piezoelectric material, then taking a substrate, and bonding it to the side of the piezoelectric material with the reflecting layer;

Or, taking a piece of ion-implanted piezoelectric material, and then taking a substrate, growing reflecting layers above the said substrate, and bonding the said piezoelectric material to the side of the substrate with the reflecting layer;

Or, taking a piece of ion-implanted piezoelectric material, and growing reflecting layers below the implantation face of the said piezoelectric material, then taking a substrate, growing reflecting layers above the said substrate, and bonding the side of the piezoelectric material with the reflecting layer to the side of the substrate with the reflecting layer;

(b) Heating the bonded intermediate product gained from step (a) to strip the film from the said piezoelectric material and growing an upper electrode on the stripped side of the said piezoelectric material;

Preferably, the piezoelectric material mentioned in step (a) is lithium niobate;

Preferably, the ion-implanted piezoelectric material is obtained by using the following method: taking a piece of piezoelectric material and implanting ions into the said piezoelectric material; the ion implanted can be at least one member selected from the group consisting of H ion, He ion, B ion and As ion; energy of the implanted ion is 100 KeV-1000 KeV; the implantation dose is 2-8×10¹⁶/cm², the ion beam current is 0.1-10 um/cm⁻²; and the implantation depth is 0.3-8 um;

Preferably, the said substrate is Si, SOI glass, LN or LT.

Preferably, the said reflecting layer includes low acoustic impedance reflecting layer and high acoustic impedance reflecting layer; the said low acoustic impedance reflecting layers and high acoustic impedance reflecting layers are arranged alternately, with the layer closest to the said piezoelectric material being a low acoustic impedance reflecting layer;

Preferably, the said low acoustic impedance reflecting layer is made of at least one member selected from the group consisting of Al, Ti, SiO₂ and BCB; the said high acoustic impedance reflecting layer is made of at least one member selected from the group consisting of Mo, Au, Nb, Ni, Pt, Ta, W, Ir, ZnO, HfO₂, TiO₂, Ta₂O₅ and WO₃.

Preferably, the specific steps for growing reflecting layers are as follows:

Growing a low acoustic impedance reflecting layer on one side of the said piezoelectric material, then growing a high acoustic impedance reflecting layer on the previous low acoustic impedance reflecting layer, and repeating the operation for 1-4 cycles;

Or, growing a high acoustic impedance reflecting layer above the said substrate, then growing a low acoustic impedance reflecting layer on the previous high acoustic impedance reflecting layer, repeating the operation for 1-3 cycles, and at last growing a high acoustic impedance reflecting layer on the low acoustic impedance reflecting layer;

Or, growing a low acoustic impedance reflecting layer on one side of the said piezoelectric material, then growing a high acoustic impedance reflecting layer on the previous low acoustic impedance reflecting layer, and repeating the operation for 1-2 cycles; at the same time, growing a high acoustic impedance reflecting layer above the said substrate, then growing a low acoustic impedance reflecting layer on the previous high acoustic impedance reflecting layer, repeating the operation for 1-2 cycles, and at last growing a high acoustic impedance reflecting layer on the low acoustic impedance reflecting layer;

Preferably, the total thickness of the said reflecting layers grown is 200 nm-6000 nm.

Preferably, the bonding mentioned in step (a) is polymer bonding, hydrophilic bonding or eutectic bonding;

Preferably, the specific steps for polymer bonding are as follows: applying bonding material on one side of the said substrate and/or piezoelectric material; the said bonding material is organic insulating material; the said organic insulating material includes at least one member selected from the group consisting of benzocyclobutene and polyimide; preferably, the thickness of the said bonding material applied is 100 nm-4000 nm;

Preferably, the specific steps for hydrophilic bonding are as follows: applying bonding material on one side of the said substrate and/or piezoelectric material; the said bonding material is at least one member selected from the group consisting of silicon oxide, silicon nitride, aluminum oxide and aluminum nitride; preferably, the thickness of the said bonding material applied is 100 nm-4000 nm;

Preferably, the specific steps for eutectic bonding are as follows: applying bonding material on one side of the said substrate and/or piezoelectric material; the said bonding material is at least one member selected from the group consisting of gold, tin and their alloys; preferably, the thickness of the said bonding material applied is 100 nm-4000 nm.

Preferably, on the implantation face of the ion-implanted piezoelectric material in step (a) also grows a lower electrode;

Preferably, the said lower electrode includes graphical lower electrode and non-graphical lower electrode;

Preferably, the method for growing a graphical lower electrode is as follows: photoetching the pattern to be grown on the surface of the said piezoelectric material, then growing an electrode, and at last washing off the unwanted part; or, first growing an electrode on the surface of the said piezoelectric material, then preparing a mask, and at last etching off the unwanted part;

Preferably, the material for growing the lower electrode is Al, Au, Mo, Pt or W; the thickness of the said lower electrode is 50-500 nm.

Preferably, the said lower electrode is a graphical lower electrode and SiO₂ is grown on one side of the said lower electrode as an isolating layer which may or may not be subject to planarization; the thickness of the said isolating layer is 50-800 nm and preferably 50-100 nm.

Preferably, step (b) comprises the following specific procedures: heating the bonded intermediate product gained from step (a) to 200-350° C. to strip the film and then annealing at 200-350° C. for 20-120 min to get the stripped film; preferably, the thickness of the said piezoelectric material after stripping is 500-1000 nm.

Preferably, the material for growing the said upper electrode is Al, Au, Mo, Pt or W; the thickness of the said upper electrode is 50-300 nm.

The present invention also provides a solid reflection-type bulk acoustic resonator prepared by the said preparation method of solid reflection-type bulk acoustic resonator.

Preferably, the solid reflection-type bulk acoustic resonator consists of an upper electrode, a piezoelectric film, a lower electrode, a reflecting layer, a bonding layer and a substrate from top to bottom; preferably, the said lower electrode is a graphical lower electrode and an isolating layer is set between the said lower electrode and the said reflecting layer;

Or, it consists of an upper electrode, a piezoelectric film, a lower electrode, a bonding layer, a reflecting layer and a substrate from top to bottom.

Preferably, the said reflecting layer consists of low acoustic impedance reflecting layers and high acoustic impedance reflecting layers arranged alternately.

The present invention also provides a solid reflection-type bulk acoustic resonator, characterized in that:

It consists of an upper electrode, a piezoelectric film, a lower electrode, a reflecting layer, a bonding layer and a substrate from top to bottom; preferably, the said lower electrode is a graphical lower electrode and an isolating layer is set between the said lower electrode and the said reflecting layer;

Or, it consists of an upper electrode, a piezoelectric film, a lower electrode, a bonding layer, a reflecting layer and a substrate from top to bottom;

Preferably, the said reflecting layer consists of low acoustic impedance reflecting layers and high acoustic impedance reflecting layers arranged alternately;

Preferably, the said solid reflection-type bulk acoustic resonator is prepared by way of wafer bonding and lay transfer.

Compared with the prior arts, the present invention has the following beneficial effects:

1. According to the preparation method of solid reflection-type bulk acoustic resonator disclosed in the present invention, resonators with high strength and good performance can be prepared by using wafer bonding and lay transfer technique for preparing high-quality piezoelectric films and combining the solid reflecting layer structure. In the present invention, the bonding layer can be designed at any position between the lower electrode and the substrate. The present invention allows for flexible bonding modes to satisfy the requirements in different preparation conditions, so as to improve the success rate of bonding. Furthermore, the solid reflection-type bulk acoustic resonator prepared by the preparation method disclosed in the present invention can satisfy the requirements of high frequency, high electromechanical coupling coefficient and broad band filtering, with low occurrence of harmonic waves, thus solving the technical problems existing in the solid reflection-type bulk acoustic resonator prepared by way of electron beam deposition, such as difficulty in ensuring the proper lattice orientation, poor film quality, huge impact on resonance frequency due to the generation of multiple harmonic waves by the device and difficulty in satisfying the requirement of broad band filtering.

2. According to the preparation method of solid reflection-type bulk acoustic resonator disclosed in the present invention, low acoustic impedance reflecting layers and high acoustic impedance reflecting layers are arranged alternately and grown layer by layer. When multiple layers of materials are grown, the roughness will increase and the film quality will deteriorate with the increase in number of layers, but the quality of the reflecting layer closest to the piezoelectric material has the largest impact on the reflection effect of the acoustic waves from the solid reflecting layer. The present invention can ensure the good quality of the reflecting layer closest to the piezoelectric material by way of growing the reflecting layer directly on the piezoelectric material, thus avoiding the adverse impact of poor quality of films grown layer by layer on the performance of resonators.

### BRIEF DESCRIPTION OF THE DRAWINGS

FIG. 1 is a process diagram for the preparation method of solid reflection-type bulk acoustic resonator disclosed in Embodiment 1.

FIG. 2 is a process diagram for the preparation method of solid reflection-type bulk acoustic resonator disclosed in Embodiment 2.

FIG. 3 is a process diagram for the preparation method of solid reflection-type bulk acoustic resonator disclosed in Embodiment 3.

FIG. 4 is a process diagram for the preparation method of solid reflection-type bulk acoustic resonator disclosed in Embodiment 4.

FIG. 5 is a process diagram for the preparation method of solid reflection-type bulk acoustic resonator disclosed in Embodiment 5.

FIG. 6 is a process diagram for the preparation method of solid reflection-type bulk acoustic resonator disclosed in Embodiment 6.

FIG. 7 is a process diagram for the preparation method of solid reflection-type bulk acoustic resonator disclosed in Embodiment 7.

FIG. 8 is a process diagram for the preparation method of solid reflection-type bulk acoustic resonator disclosed in Embodiment 8.

FIG. 9 is a process diagram for the preparation method of solid reflection-type bulk acoustic resonator disclosed in Embodiment 9.

FIG. 10 is a process diagram for the preparation method of solid reflection-type bulk acoustic resonator disclosed in Embodiment 10.

FIG. 11 is a process diagram for the preparation method of solid reflection-type bulk acoustic resonator disclosed in Embodiment 11.

FIG. 12 is a structure diagram for the solid reflection-type bulk acoustic resonator obtained in Embodiment 1.

In the figure: 1—upper electrode; 2—piezoelectric film; 3—lower electrode; 4—low acoustic impedance reflecting layer; 5—high acoustic impedance reflecting layer; 6—bonding layer; 7—substrate.

### DETAILED DESCRIPTION OF THE PREFERRED EMBODIMENTS

The technical solution in the embodiments of the present invention will be described clearly and completely below in combination with the accompanying drawings in the embodiments of the present invention. Obviously, the described embodiments are only part of the embodiments of the present invention, not all of them. All other embodiments obtained by a person of ordinary skill in the art based on the embodiments of the present invention without creative labor shall fall with the scope of protection of the present invention.

It should be noted that, where no specific conditions are indicated in the embodiments of the present invention, the normal conditions or those suggested by the manufacturer shall apply; where no manufacturers are indicated for the agent or device used, the commercially available conventional products shall apply; raw materials from different manufacturers and of different models will not affect the implementation of the technical solution and realization of the technical effect disclosed in the present invention.

### Embodiment 1

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

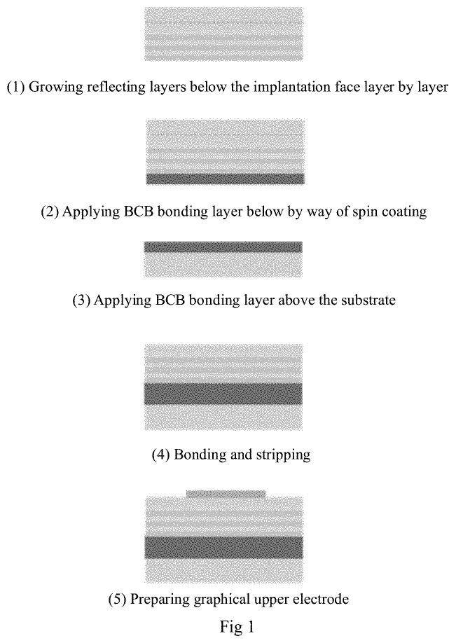

As a preferred implementation mode of this embodiment, the preparation method of solid reflection-type bulk acoustic resonator, as shown in FIG. 1, comprises the following specific steps:

(a) As shown in FIG. 1(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

It should be noted that, as an alternative implementation mode of this embodiment, the ion to be implanted can also be at least one member selected from the group consisting of He ion, B ion and As ion; energy of the implanted ion can be any value between 100 KeV-1000 KeV; the implantation dose can be any value between 2—8×10¹⁶/cm²; the ion beam current can be any value between 0.1-10 um/cm⁻²; and the implantation depth can be any value between 0.3-8 um.

Growing reflecting layers below the implantation face of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3600 nm. The said reflecting layer includes low acoustic impedance reflecting layer and high acoustic impedance reflecting layer; and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, polymer bonding is applied; applying bonding material on one side of the said substrate and/or piezoelectric material; wherein the said bonding material is organic insulating material and the said organic insulating material includes but not limited to benzocyclobutene and polyimide; the thickness of the said bonding material applied is 100 nm-4000 nm; in this embodiment, the specific procedures are as follows:

As shown in FIG. 1(2), applying bonding material on the said reflecting layer by way of spin coating to form a bonding layer; in this embodiment, the said bonding material is benzocyclobutene (BCB);

As shown in FIG. 1(3), applying bonding material above the said substrate by way of spin coating to form a bonding layer, wherein the said bonding material is benzocyclobutene (BCB); in this embodiment, the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material applied with the bonding layer into a bonder or a tube furnace for bonding at a prebonding pressure of 4×10⁵ pa for 30 min; then slowly raising the temperature to 200° C. and maintaining the temperature for 2 h to allow the benzocyclobutene to fully cure and thus to obtain the bonded intermediate product.

(b) Annealing the bonded intermediate product gained from step (a) at 350° C. for 2 h to make the piezoelectric material split along the damaged layer caused by the ion implantation, so as to obtain the single-crystal piezoelectric thin film, i.e., the piezoelectric layer, as shown in FIG. 1(4). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 1(5).

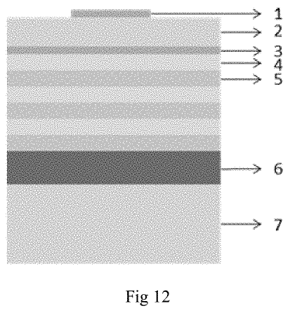

The structural schematic diagram of the solid reflection-type bulk acoustic resonator prepared is shown in FIG. 12.

### Embodiment 2

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

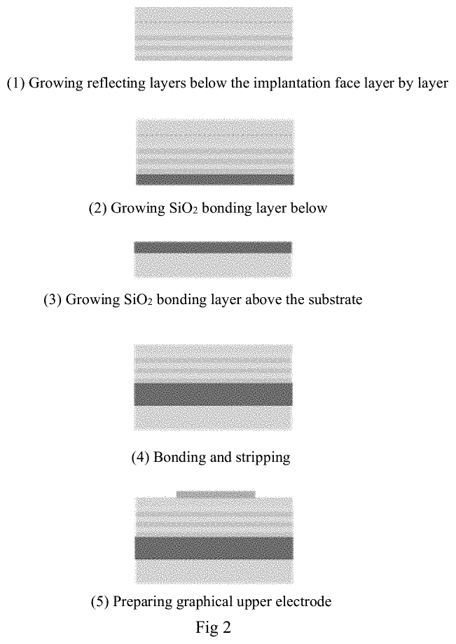

As a preferred implementation mode of this embodiment, the preparation method of solid reflection-type bulk acoustic resonator, as shown in FIG. 2, comprises the following specific steps:

(a) As shown in FIG. 2(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing reflecting layers below the implantation face of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer; wherein the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, hydrophilic bonding is applied; applying bonding material on one side of the said substrate and/or piezoelectric material; wherein the said bonding material is at least one member selected from the group consisting of silicon oxide, silicon nitride, aluminum oxide and aluminum nitride and the thickness of the said bonding material applied is 100 nm-4000 nm; in this embodiment, the specific procedures are as follows:

As shown in FIG. 2(2), growing bonding material on the said reflecting layer to form a bonding layer; in this embodiment, the said bonding material is silicon dioxide (SiO₂);

As shown in FIG. 2(3), growing bonding material above the said substrate to form a bonding layer; the said bonding material is silicon dioxide (SiO₂); in this embodiment, the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material grown with the bonding layer into a bonder or a tube furnace for bonding to obtain the bonded intermediate product.

(b) Annealing the bonded intermediate product gained from step (a) at 200° C. for 2 h to make the piezoelectric material split along the damaged layer caused by the ion implantation, so as to obtain the single-crystal piezoelectric thin film, as shown in FIG. 2(4). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 2(5).

### Embodiment 3

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

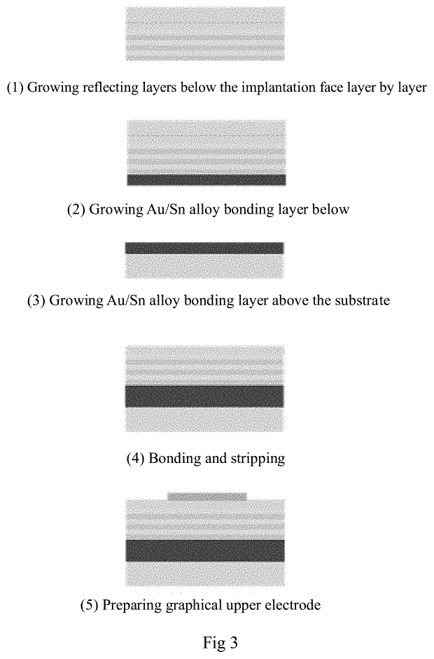

As a preferred implementation mode of this embodiment, the preparation method of solid reflection-type bulk acoustic resonator, as shown in FIG. 3, comprises the following specific steps:

(a) As shown in FIG. 3(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing reflecting layers below the implantation face of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, eutectic bonding is applied; applying bonding material on one side of the said substrate and/or piezoelectric material; wherein the said bonding material is at least one member selected from the group consisting of gold, tin and their alloys; preferably, the thickness of the said bonding material applied is 100 nm-4000 nm; in this embodiment, the specific procedures are as follows:

As shown in FIG. 3(2), growing bonding material on the said reflecting layer to form a bonding layer; in this embodiment, the said bonding material is gold and tin, i.e., Au/Sn;

As shown in FIG. 3(3), growing bonding material above the said substrate to form a bonding layer; the said bonding material is gold and tin, i.e., Au/Sn; in this embodiment, the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material grown with the bonding layer into a bonder or a tube furnace for bonding to obtain the bonded intermediate product.

(b) Annealing the bonded intermediate product gained from step (a) at 200° C. for 2 h to make the piezoelectric material split along the damaged layer caused by the ion implantation, so as to obtain the single-crystal piezoelectric thin film, as shown in FIG. 3(4). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 3(5).

### Embodiment 4

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

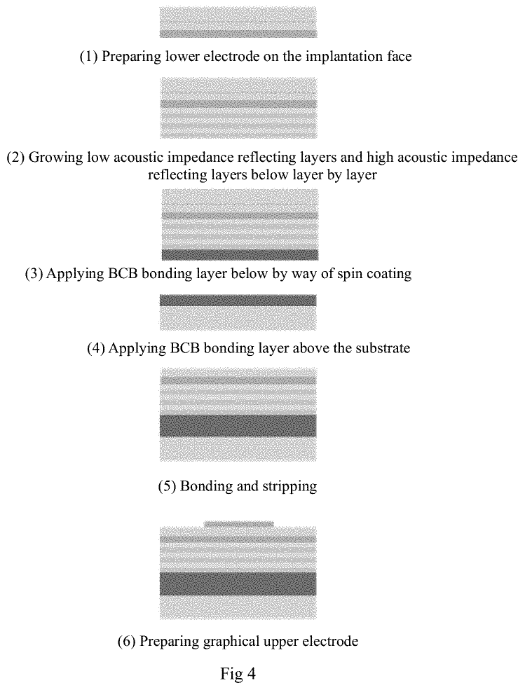

As a preferred implementation mode of this embodiment, the preparation method of solid reflection-type bulk acoustic resonator, as shown in FIG. 4, comprises the following specific steps:

(a) As shown in FIG. 4(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

It should be noted that, as an alternative implementation mode of this embodiment, the ion to be implanted can also be at least one member selected from the group consisting of He ion, B ion and As ion; energy of the implanted ion can be any value between 100-1000 KeV; the implantation dose can be any value between 2-8×10¹⁶/cm²; the ion beam current can be any value between 0.1-10 um/cm⁻²; and the implantation depth can be any value between 0.3-8 um.

Growing a lower electrode above the implantation face of the ion-implanted piezoelectric material; the said lower electrode is a non-graphical lower electrode; the material for growing the lower electrode is Al; the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 4(2), growing reflecting layers below the implantation face of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3600 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, polymer bonding is applied; applying bonding material on one side of the said substrate and/or piezoelectric material; wherein the said bonding material is organic insulating material and the said organic insulating material includes but not limited to benzocyclobutene and polyimide; the thickness of the said bonding material applied is 100 nm-4000 nm; in this embodiment, the specific procedures are as follows:

As shown in FIG. 4(3), applying bonding material on the said reflecting layer by way of spin coating to form a bonding layer; in this embodiment, the said bonding material is benzocyclobutene (BCB);

As shown in FIG. 4(4), applying bonding material on the said substrate by way of spin coating to form a bonding layer; the said bonding material is benzocyclobutene (BCB); in this embodiment, the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material applied with the bonding layer into a bonder or a tube furnace for bonding at a prebonding pressure of 4×10⁵ pa for 30 min; then slowly raising the temperature to 200° C. and maintaining the temperature for 2 h to allow the benzocyclobutene to fully cure and thus to obtain the bonded intermediate product.

(b) Annealing the bonded intermediate product gained from step (a) at 350° C. for 2 h to make the piezoelectric material split along the damaged layer caused by the ion implantation, so as to obtain the single-crystal piezoelectric thin film, i.e., the piezoelectric layer, as shown in FIG. 4(5). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 4(6).

### Embodiment 5

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

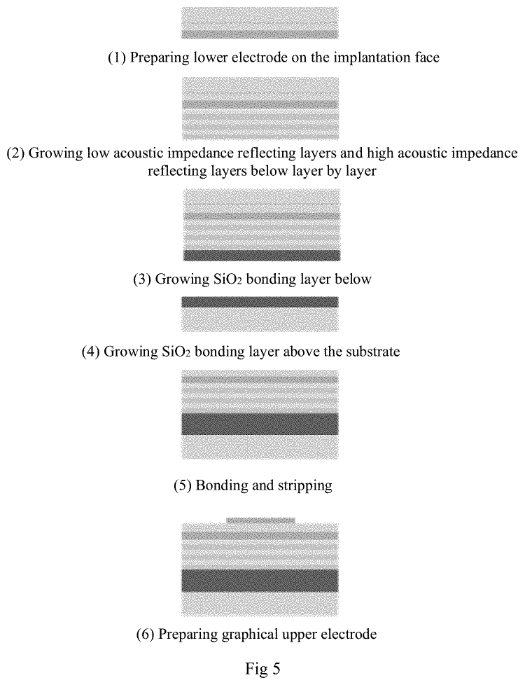

As a preferred implementation mode of this embodiment, the preparation method of solid reflection-type bulk acoustic resonator, as shown in FIG. 5, comprises the following specific steps:

(a) As shown in FIG. 5(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; the said lower electrode is a non-graphical lower electrode; the material for growing the lower electrode is Al; the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 5(2), growing reflecting layers below the implantation face of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, hydrophilic bonding is applied; applying bonding material on one side of the said substrate and/or piezoelectric material; wherein the said bonding material is at least one member selected from the group consisting of silicon oxide, silicon nitride, aluminum oxide and aluminum nitride and the thickness of the said bonding material applied is 100 nm-4000 nm; in this embodiment, the specific procedures are as follows:

As shown in FIG. 5(3), growing bonding material on the said reflecting layer to form a bonding layer; in this embodiment, the said bonding material is silicon dioxide (SiO₂);

As shown in FIG. 5(4), growing bonding material above the said substrate to form a bonding layer; the said bonding material is silicon dioxide (SiO₂); in this embodiment, the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material grown with the bonding layer into a bonder or a tube furnace for bonding to obtain the bonded intermediate product.

(b) Annealing the bonded intermediate product gained from step (a) at 200° C. for 2 h to make the piezoelectric material split along the damaged layer caused by the ion implantation, so as to obtain the single-crystal piezoelectric thin film, as shown in FIG. 5(5). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 5(6).

### Embodiment 6

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

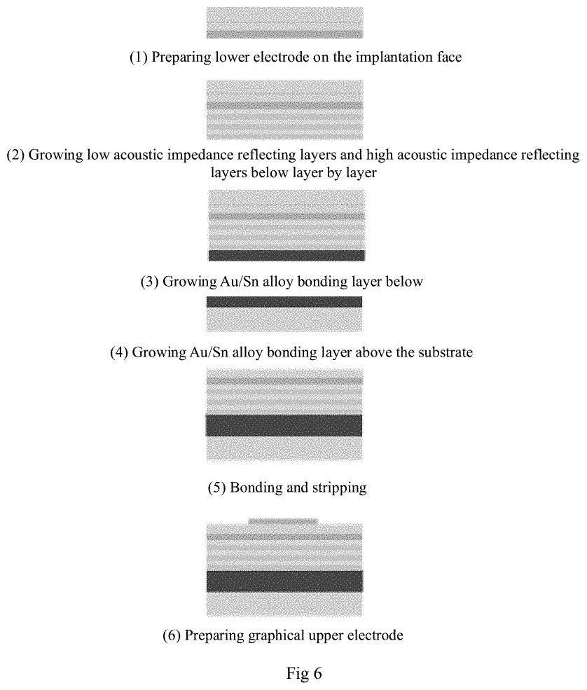

As a preferred implementation mode of this embodiment, the preparation method of solid reflection-type bulk acoustic resonator, as shown in FIG. 6, comprises the following specific steps:

(a) As shown in FIG. 6(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; the said lower electrode is a non-graphical lower electrode; the material for growing the lower electrode is Al; the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 6(2), growing reflecting layers below the implantation face of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, eutectic bonding is applied; applying bonding material on one side of the said substrate and/or piezoelectric material; wherein the said bonding material is at least one member selected from the group consisting of gold, tin and their alloys; preferably, the thickness of the said bonding material applied is 100 nm-4000 nm; in this embodiment, the specific procedures are as follows:

As shown in FIG. 6(3), growing bonding material on the said reflecting layer to form a bonding layer; in this embodiment, the said bonding material is gold and tin, i.e., Au/Sn;

As shown in FIG. 6(4), growing bonding material above the said substrate to form a bonding layer; the said bonding material is gold and tin, i.e., Au/Sn; in this embodiment, the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material grown with the bonding layer into a bonder or a tube furnace for bonding to obtain the bonded intermediate product.

(b) Annealing the bonded intermediate product gained from step (a) at 200° C. for 2 h to make the piezoelectric material split along the damaged layer caused by the ion implantation, so as to obtain the single-crystal piezoelectric thin film, as shown in FIG. 6(5). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 6(6).

### Embodiment 7

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

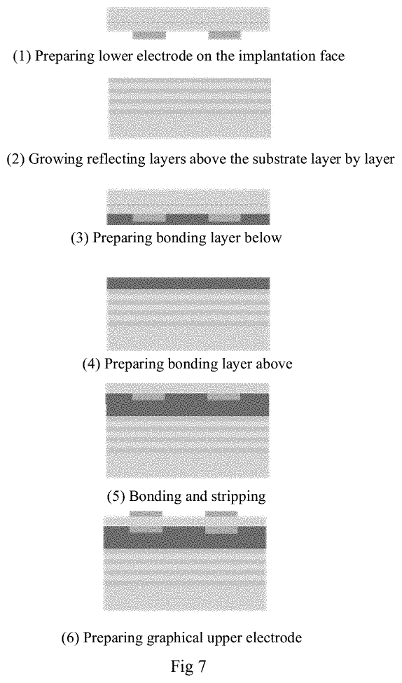

As a preferred implementation mode of this embodiment, the preparation method of solid reflection-type bulk acoustic resonator, as shown in FIG. 7, comprises the following specific steps:

(a) As shown in FIG. 7(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; the said lower electrode is a graphical lower electrode. The method for growing a graphical lower electrode is as follows: photoetching a pattern to be grown on the surface of the said piezoelectric material, then growing an electrode, and at last washing off the unwanted part; as an alternative implementation mode of this embodiment, the said lower electrode can also be grown by the following method: first growing an electrode on the surface of the said piezoelectric material, then preparing a mask, and at last etching off the unwanted part; in this embodiment, the material for growing the lower electrode is Al; the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 7(2), taking a substrate; in this embodiment, the said substrate is made of Si, and as an alternative implementation mode of this embodiment, the said substrate can also be made of silicon-on-insulator (SOI), glass, lithium niobate (LN) or lithium tantalate (LT).

Growing a high acoustic impedance reflecting layer above the said substrate, then growing a low acoustic impedance reflecting layer on the previous high acoustic impedance reflecting layer, repeating the operation for 1-3 cycles, and at last growing a high acoustic impedance reflecting layer on the low acoustic impedance reflecting layer; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, bonding the piezoelectric material to the side of the said substrate with reflecting layer; in this embodiment, polymer bonding is applied; applying bonding material on one side of the said substrate and/or piezoelectric material; wherein the said bonding material is organic insulating material and the said organic insulating material includes but not limited to benzocyclobutene and polyimide; the thickness of the said bonding material applied is 100 nm-4000 nm; in this embodiment, the specific procedures are as follows:

As shown in FIG. 7(3), applying bonding material on the side of the piezoelectric material with the lower electrode by way of spin coating to form a bonding layer; in this embodiment, the said bonding material is benzocyclobutene (BCB);

As shown in FIG. 7(4), applying bonding material on the side of the substrate with the reflecting layer by way of spin coating to form a bonding layer; in this embodiment, the said bonding material is benzocyclobutene (BCB);

Placing the said substrate and piezoelectric material applied with the bonding layer into a bonder or a tube furnace for bonding at a prebonding pressure of 4×10⁵ pa for 30 min; then slowly raising the temperature to 200° C. and maintaining the temperature for 2 h to allow the benzocyclobutene to fully cure and thus to obtain the bonded intermediate product.

(b) Annealing the bonded intermediate product gained from step (a) at 350° C. for 2 h to make the piezoelectric material split along the damaged layer caused by the ion implantation, so as to obtain the single-crystal piezoelectric thin film, i.e., the piezoelectric layer, as shown in FIG. 7(5). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 7(6).

### Embodiment 8

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

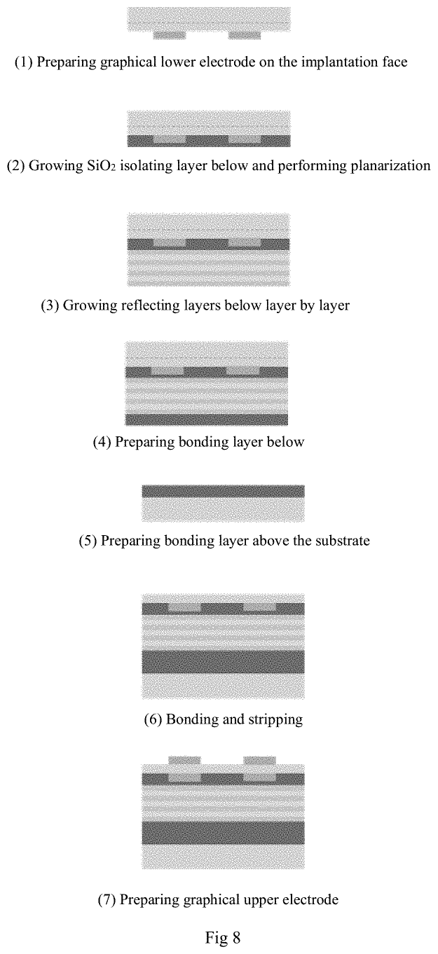

As a preferred implementation mode of this embodiment, the preparation method of solid reflection-type bulk acoustic resonator, as shown in FIG. 8, comprises the following specific steps:

(a) As shown in FIG. 8(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; the said lower electrode is a graphical lower electrode. The method for growing a graphical lower electrode is as follows: photoetching a pattern to be grown on the surface of the said piezoelectric material, then growing an electrode, and at last washing off the unwanted part; as an alternative implementation mode of this embodiment, the said lower electrode can also be grown by the following method: first growing an electrode on the surface of the said piezoelectric material, then preparing a mask, and at last etching off the unwanted part; in this embodiment, the material for growing the lower electrode is Al and the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 8(2), growing SiO₂ on one side of the said lower electrode as an isolating layer and then planarize the isolating layer; the thickness of the said isolating layer is 50 nm. As an alternative implantation mode of this embodiment, the thickness of the said isolating layer can be any value between 50-800 nm.

As shown in FIG. 8(3), growing reflecting layers below the isolating layer of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, polymer bonding is applied; applying bonding material on one side of the said substrate and/or piezoelectric material; wherein the said bonding material is organic insulating material and the said organic insulating material includes but not limited to benzocyclobutene and polyimide; the thickness of the said bonding material applied is 100 nm-4000 nm; in this embodiment, the specific procedures are as follows:

As shown in FIG. 8(4), applying bonding material on the side of the piezoelectric material with the reflecting layer by way of spin coating to form a bonding layer; in this embodiment, the said bonding material is benzocyclobutene (BCB);

As shown in FIG. 8(5), applying bonding material on the side of the substrate with the reflecting layer by way of spin coating to form a bonding layer; the said bonding material is benzocyclobutene (BCB) and the said substrate is made of Si. As an alternative implementation mode of this embodiment, the said substrate can also be made of silicon-on-insulator (SOI), glass, lithium niobate (LN) or lithium tantalate (LT).

Placing the said substrate and piezoelectric material applied with the bonding layer into a bonder or a tube furnace for bonding at a prebonding pressure of 4×10⁵ pa for 30 min; then slowly raising the temperature to 200° C. and maintaining the temperature for 2 h to allow the benzocyclobutene to fully cure and thus to obtain the bonded intermediate product.

(b) Annealing the bonded intermediate product gained from step (a) at 350° C. for 2 h to make the piezoelectric material split along the damaged layer caused by the ion implantation, so as to obtain the single-crystal piezoelectric thin film, i.e., the piezoelectric layer, as shown in FIG. 8(6). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 8(7).

### Embodiment 9

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, growing reflecting layers above the said substrate, and bonding the side of the piezoelectric material with the reflecting layer to the side of the substrate with the reflecting layer;

(b) Heating the bonded intermediate product gained from step (a) to strip the film from the said piezoelectric material and growing an upper electrode on the stripped side of the said piezoelectric material.

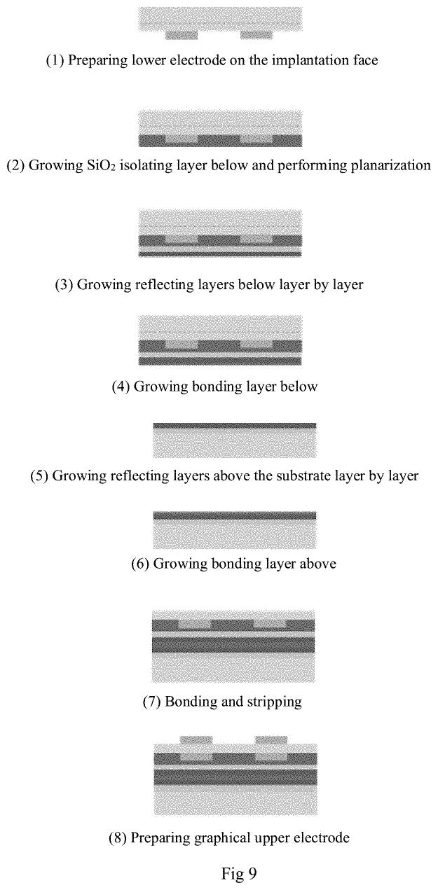

As a preferred implementation mode of this embodiment, the preparation method of solid reflection-type bulk acoustic resonator, as shown in FIG. 9, comprises the following specific steps:

(a) As shown in FIG. 9(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; the said lower electrode is a graphical lower electrode. The method for growing a graphical lower electrode is as follows: photoetching the pattern to be grown on the surface of the said piezoelectric material, then growing an electrode, and at last washing off the unwanted part; as an alternative implementation mode of this embodiment, the said lower electrode can also be grown by the following method: first growing an electrode on the surface of the said piezoelectric material, then preparing a mask, and at last etching off the unwanted part; in this embodiment, the material for growing the lower electrode is Al and the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 9(2), growing SiO₂ on one side of the said lower electrode as an isolating layer and then planarize the isolating layer; the thickness of the said isolating layer is 50 nm. As an alternative implantation mode of this embodiment, the thickness of the said isolating layer can be any value between 50-800 nm.

As shown in FIG. 9(3), growing reflecting layers below the isolating layer of the ion-implanted piezoelectric material; The said reflecting layer includes low acoustic impedance reflecting layer and high acoustic impedance reflecting layer; the said low acoustic impedance reflecting layers and high acoustic impedance reflecting layers are arranged alternately; first, growing a low acoustic impedance reflecting layer on one side of the said piezoelectric material, then growing a high acoustic impedance reflecting layer on the previous low acoustic impedance reflecting layer, and repeating the operation for 1-2 cycles; in this embodiment, repeating the operation of growing reflecting layers for 1 cycle with the total thickness of the said reflecting layers being 300 nm. The said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, hydrophilic bonding is applied; applying bonding material on one side of the said substrate and/or piezoelectric material; wherein the said bonding material is at least one member selected from the group consisting of silicon oxide, silicon nitride, aluminum oxide and aluminum nitride and preferably the thickness of the said bonding material applied is 100 nm-4000 nm; in this embodiment, the specific procedures are as follows:

As shown in FIG. 9(4), growing bonding material on the said reflecting layer to form a bonding layer; in this embodiment, the said bonding material is silicon dioxide (SiO₂);

As shown in FIG. 9(5), taking a substrate; in this embodiment, the said substrate is made of Si, and as an alternative implementation mode of this embodiment, the said substrate can also be made of silicon-on-insulator (SOI), glass, lithium niobate (LN) or lithium tantalate (LT).

Growing a high acoustic impedance reflecting layer above the said substrate, then growing a low acoustic impedance reflecting layer on the previous high acoustic impedance reflecting layer, repeating the operation for 1-2 cycles, and at last growing a high acoustic impedance reflecting layer on the low acoustic impedance reflecting layer. In this embodiment, repeating the operation of growing reflecting layers for 1 cycle, with the total thickness of the said reflecting layers being 300 nm. The said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

As shown in FIG. 9(6), growing bonding material above the said substrate to form a bonding layer; the said bonding material is silicon dioxide (SiO₂); placing the said substrate and piezoelectric material grown with the bonding layer into a bonder or a tube furnace for bonding to obtain the bonded intermediate product.

(b) Annealing the bonded intermediate product gained from step (a) at 200° C. for 2 h to make the piezoelectric material split along the damaged layer caused by the ion implantation, so as to obtain the single-crystal piezoelectric thin film, as shown in FIG. 9(7). At last, growing an upper electrode on the stripped side of the said piezoelectric material. In this embodiment, a graphical upper electrode is grown; first, photoetching the pattern to be grown on the surface of the said piezoelectric material, then growing an electrode, and at last washing off the unwanted part; the upper electrode is made of AI and the thickness of the said upper electrode is 50 nm, as shown in FIG. 9(8).

### Embodiment 10

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, growing reflecting layers above the said substrate, and bonding the side of the piezoelectric material with the reflecting layer to the side of the substrate with the reflecting layer;

(b) Heating the bonded intermediate product gained from step (a) to strip the film from the said piezoelectric material and growing an upper electrode on the stripped side of the said piezoelectric material.

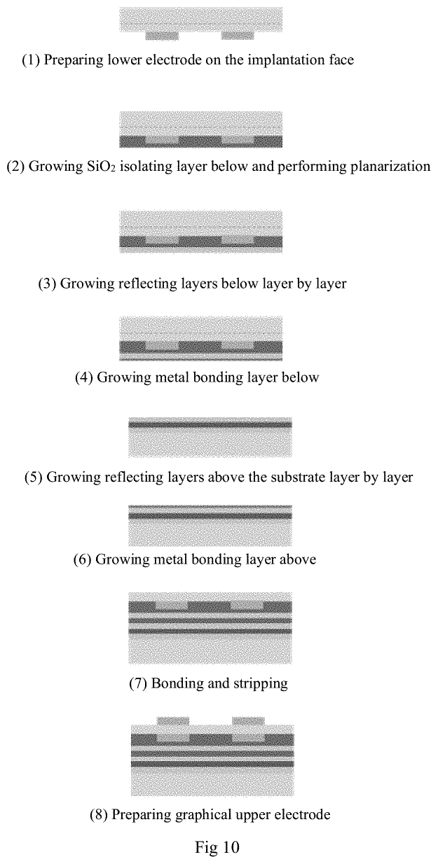

As a preferred implementation mode of this embodiment, the preparation method of solid reflection-type bulk acoustic resonator, as shown in FIG. 10, comprises the following specific steps:

(a) As shown in FIG. 10(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; wherein the said lower electrode is a graphical lower electrode. The method for growing a graphical lower electrode is as follows: photoetching the pattern to be grown on the surface of the said piezoelectric material, then growing an electrode, and at last washing off the unwanted part. As an alternative implementation mode of this embodiment, the said lower electrode can also be grown by the following method: first growing an electrode on the surface of the said piezoelectric material, then preparing a mask, and at last etching off the unwanted part; in this embodiment, the material for growing the lower electrode is Al and the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 10(2), growing SiO₂ on one side of the said lower electrode as an isolating layer and then planarize the isolating layer; the thickness of the said isolating layer is 50 nm. As an alternative implantation mode of this embodiment, the thickness of the said isolating layer can be any value between 50-800 nm.

As shown in FIG. 10(3), growing reflecting layers below the isolating layer of the ion-implanted piezoelectric material; The said reflecting layer includes low acoustic impedance reflecting layer and high acoustic impedance reflecting layer; the said low acoustic impedance reflecting layers and high acoustic impedance reflecting layers are arranged alternately; first, growing a low acoustic impedance reflecting layer on one side of the said piezoelectric material, then growing a high acoustic impedance reflecting layer on the previous low acoustic impedance reflecting layer, and repeating the operation for 1-2 cycles; in this embodiment, repeating the operation of growing reflecting layers for 1 cycle with the total thickness of the said reflecting layers being 300 nm. The said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃. Then, taking a substrate and bonding it to the side of the piezoelectric material with the reflecting layer; in this embodiment, eutectic bonding is applied; applying bonding material on one side of the said substrate and/or piezoelectric material; the said bonding material is at least one member selected from the group consisting of gold, tin and their alloys; preferably, the thickness of the said bonding material applied is 100 nm-4000 nm; in this embodiment, the specific procedures are as follows:

As shown in FIG. 10(4), growing bonding material on the said reflecting layer to form a bonding layer; in this embodiment, the said bonding material is gold and tin, i.e., Au/Sn;

As shown in FIG. 10(5), taking a substrate; in this embodiment, the said substrate is made of Si, and as an alternative implementation mode of this embodiment, the said substrate can also be made of silicon-on-insulator (SOI), glass, lithium niobate (LN) or lithium tantalate (LT).

Growing a high acoustic impedance reflecting layer above the said substrate, then growing a low acoustic impedance reflecting layer on the previous high acoustic impedance reflecting layer, repeating the operation for 1-2 cycles, and at last growing a high acoustic impedance reflecting layer on the low acoustic impedance reflecting layer. In this embodiment, repeating the operation of growing reflecting layers for 1 cycle, with the total thickness of the said reflecting layers being 300 nm. The said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

As shown in FIG. 10(6), growing bonding material on the said substrate to form a bonding layer; in this embodiment, the said bonding material is gold and tin, i.e., Au/Sn; placing the said substrate and piezoelectric material grown with the bonding layer into a bonder or a tube furnace for bonding to obtain the bonded intermediate product.

(b) Annealing the bonded intermediate product gained from step (a) at 200° C. for 2 h to make the piezoelectric material split along the damaged layer caused by the ion implantation, so as to obtain the single-crystal piezoelectric thin film, as shown in FIG. 10(7). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 10(8).

### Embodiment 11

In this embodiment, the preparation method of solid reflection-type bulk acoustic resonator comprises the following steps:

(a) Taking a piece of ion-implanted piezoelectric material, growing reflecting layers below the implantation face of the said piezoelectric material, then taking a substrate, and bonding it to the side of the piezoelectric material with the reflecting layer;

(b) Heating the bonded intermediate product gained from step (a) to strip the film from the said piezoelectric material and growing an upper electrode on the stripped side of the said piezoelectric material.

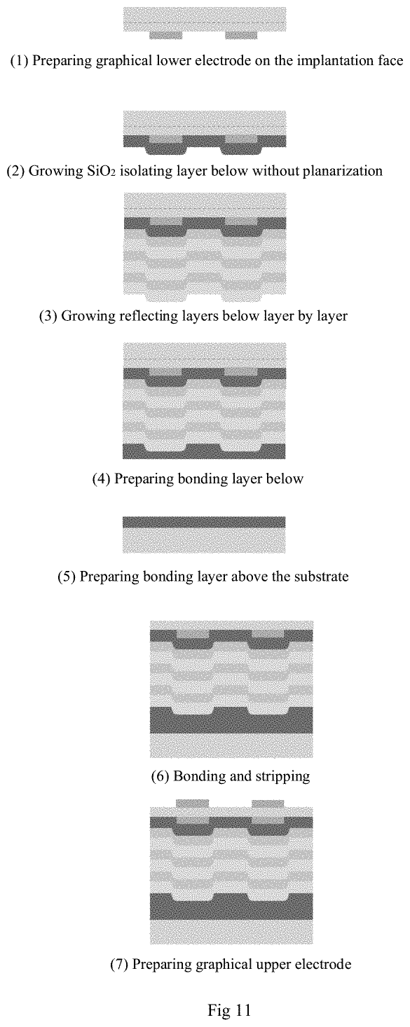

As a preferred implementation mode of this embodiment, the preparation method of solid reflection-type bulk acoustic resonator, as shown in FIG. 11, comprises the following specific steps:

(a) As shown in FIG. 11(1), taking a piece of piezoelectric material—lithium niobate and implanting H ions into the said piezoelectric material, with the energy of the implanted ion being 100 KeV, the implantation dose 2×10¹⁶/cm², the ion beam current 10 um/cm⁻², and the implantation depth 4 um, so that the ion-implanted piezoelectric material is obtained.

Growing a lower electrode above the implantation face of the ion-implanted piezoelectric material; wherein the said lower electrode is a graphical lower electrode. The method for growing a graphical lower electrode is as follows: photoetching a pattern to be grown on the surface of the said piezoelectric material, then growing an electrode, and at last washing off the unwanted part; as an alternative implementation mode of this embodiment, the said lower electrode can also be grown by the following method: first growing an electrode on the surface of the said piezoelectric material, then preparing a mask, and at last etching off the unwanted part; in this embodiment, the material for growing the lower electrode is Al; the thickness of the said lower electrode is 50 nm. As an alternative implementation mode of this embodiment, the material for growing the lower electrode can also be Au, Mo, Pt or W; the thickness of the said lower electrode can be any value between 50-500 nm.

As shown in FIG. 11(2), growing SiO₂ on one side of the said lower electrode as an isolating layer without planarization; the thickness of the said isolating layer is 50 nm. As an alternative implantation mode of this embodiment, the thickness of the said isolating layer can be any value between 50-800 nm.

As shown in FIG. 11(3), growing reflecting layers below the isolating layer of the ion-implanted piezoelectric material; growing a low acoustic impedance reflecting layer on one side of the said piezoelectric material, then growing a high acoustic impedance reflecting layer on the previous low acoustic impedance reflecting layer, and repeating the operation for 1-4 cycles; in this embodiment, repeating the operation of growing reflecting layers for 3 cycles, with the total thickness of the said reflecting layers being 3000 nm. The said reflecting layer includes low acoustic impedance reflecting layer and high acoustic impedance reflecting layer and the said low acoustic impedance reflecting layers and high acoustic impedance reflecting layers are arranged alternately; the said low acoustic impedance reflecting layer is made of Al and the said high acoustic impedance reflecting layer is made of Mo. As an alternative implementation mode of this embodiment, the said low acoustic impedance reflecting layer can also be made of at least one member selected from the group consisting of Ti, SiO₂ and benzocyclobutene (BCB); the said high acoustic impedance reflecting layer can also be made of at least one member selected from the group consisting of Au, Nb, Ni, Pt, Ta, W, Ir, ZnO, HfO₂, TiO₂, Ta₂O₅ and WO₃.

Then, taking a substrate and bonding it to the side of the piezoelectric material with the reflecting layer; in this embodiment, polymer bonding is applied; applying bonding material on one side of the said substrate and/or piezoelectric material; the said bonding material is organic insulating material; the said organic insulating material includes but not limited to benzocyclobutene and polyimide; the thickness of the said bonding material applied is 100-4000 nm; in this embodiment, the specific procedures are as follows:

As shown in FIG. 11(4), applying bonding material on the side of the piezoelectric material with the reflecting layer by way of spin coating to form a bonding layer; in this embodiment, the said bonding material is benzocyclobutene (BCB);

As shown in FIG. 11(5), applying bonding material on the side of the substrate with the reflecting layer by way of spin coating to form a bonding layer; the said bonding material is benzocyclobutene (BCB); the said substrate is made of Si, and as an alternative implementation mode of this embodiment, the said substrate can also be made of silicon-on-insulator (SOI), glass, lithium niobate (LN) or lithium tantalate (LT).

Placing the said substrate and piezoelectric material applied with the bonding layer into a bonder or a tube furnace for bonding at a prebonding pressure of 4×10⁵ pa for 30 min; then slowly raising the temperature to 200° C. and maintaining the temperature for 2 h to allow the benzocyclobutene to fully cure and thus to obtain the bonded intermediate product.

(b) Annealing the bonded intermediate product gained from step (a) at 350° C. for 2 h to make the piezoelectric material split along the damaged layer caused by the ion implantation, so as to obtain the single-crystal piezoelectric thin film, i.e., the piezoelectric layer, as shown in FIG. 11(6). At last, growing an upper electrode on the stripped side of the said piezoelectric material. In this embodiment, a graphical upper electrode is grown; first, photoetching a pattern to be grown on the surface of the said piezoelectric material, then growing an electrode, and at last washing off the unwanted part; the upper electrode is made of AI and the thickness of the said upper electrode is 50 nm, as shown in FIG. 11(7).

### Comparative Example

In this comparative example, the preparation method of solid reflection-type bulk acoustic resonator comprises the following steps:

Taking a substrate, first growing a reflecting layer above the said substrate, then growing a lower electrode above the reflecting layer and depositing a piezoelectric layer on the lower electrode, finally growing an upper electrode on the piezoelectric layer deposited.

Wherein, the materials used in the said substrate, reflecting layer, lower electrode, piezoelectric layer and upper electrode are the same as those in Embodiment 1.

### Effect Test Example

To verify the technical effect of the preparation method of solid reflection-type bulk acoustic resonator disclosed in the present invention, the said solid reflection-type bulk acoustic resonators prepared by the methods described in embodiments 1-11 and the comparative example are taken to conduct comparative test according to the following steps:

1. Take solid reflection-type bulk acoustic resonators prepared by the methods described in embodiments 1-11 and the comparative example and test the parameter S of resonators by using the probe station and vector network analyzer to get S11 of each resonator.

2. Import the S11 of each resonator into the ADS simulation software to get the input impedance Zin of three types of devices and read the series resonance frequency fs and parallel resonance frequency fp of each resonator from the impedance curve.

3. Calculate Q value of the resonator by the following formula:

Q=f_{s/p}/2×|d(<Zin)/df|_{s/p}

4. Calculate the electromechanical coupling coefficient kₜ² by the following formula:

kₜ²=π²/4×(fp−fs)/fp

The test results are shown in the following table:

| Group | fs | fp | Q | kₜ² |
|---|---|---|---|---|
| Embodiment 1 | 3.192 GHz | 3.516 GHz | 2581 | 22.71% |
| Embodiment 2 | 3.164 GHz | 3.476 GHz | 2157 | 22.12% |
| Embodiment 3 | 3.24 GHz | 3.562 GHz | 2352 | 22.28% |
| Embodiment 4 | 3.116 GHz | 3.42 GHz | 2200 | 22.04% |
| Embodiment 5 | 3.194 GHz | 3.518 GHz | 2250 | 22.7% |
| Embodiment 6 | 3196 GHz | 3.52 GHz | 2356 | 22.69% |
| Embodiment 7 | 3.15 GHz | 3.464 GHz | 2421 | 22.3% |
| Embodiment 8 | 3.158 GHz | 3.456 GHz | 2341 | 21.25% |
| Embodiment 9 | 3.142 GHz | 3.446 GHz | 2418 | 21.74% |
| Embodiment 10 | 3.190 GHz | 3.512 GHz | 2503 | 22.59% |
| Embodiment 11 | 3.16 GHz | 3.458 GHz | 2406 | 21.24% |
| Comparative | 3.012 GHz | 3.226 GHz | 1100 | 16.35% |
| Example | | | | |

The test results show that the solid reflection-type bulk acoustic resonator prepared by the method disclosed in the present invention is superior in Q value, electromechanical coupling coefficient and performance. It can be known from the technical knowledge that the present invention can be realized by the implantation solutions without departing from the spiritual essence or necessary features. Therefore, the description of the abovementioned embodiments of the present invention is not intended to limit the scope of the claimed present invention, but only represents the selected embodiments of the present invention. All variations within or equivalent to the scope of the claimed present invention shall fall with the scope of protection of the present invention.

1. A preparation method of preparing a solid reflection-type bulk acoustic resonator, said method comprising the following steps:
(a)(i) providing a piece of ion-implanted piezoelectric material, growing a reflecting layer below an implantation face of the piezoelectric material, providing a substrate, and bonding the substrate to a side of the piezoelectric material with the reflecting layer; or
(ii) providing a piece of ion-implanted piezoelectric material, providing a substrate, growing reflecting layers above the substrate, and bonding the piezoelectric material to a side of the substrate with the reflecting layer; or
Iiii) providing a piece of ion-implanted piezoelectric material, growing a reflecting layer below an implantation face of the piezoelectric material, providing a substrate, growing a reflecting layer above the substrate, and bonding a side of the piezoelectric material with the reflecting layer to a side of the substrate with the reflecting layer; and
(b) heating a bonded intermediate product obtained from step (a) to strip a film from the piezoelectric material and growing an upper electrode on a stripped side of the piezoelectric material.

2. The preparation method according to claim 1, wherein the piezoelectric material is lithium niobate.

3. The preparation method according to claim 1, wherein the reflecting layer includes a low acoustic impedance reflecting layer and a high acoustic impedance reflecting layer which are arranged alternately.

4. The preparation method according to claim 3, wherein the bonding mentioned in step (a) is polymer bonding, hydrophilic bonding or eutectic bonding.

5. The preparation method according to claim 3, wherein on the implantation face of the ion-implanted piezoelectric material in step (a) also grows a lower electrode.

6. The preparation method according to claim 5, wherein the lower electrode is a graphical lower electrode and SiO₂ is grown on one side of the lower electrode as an isolating layer which may or may not be subject to planarization; and the thickness of the isolating layer is 50-800 nm.

7. The preparation method according to claim 6, wherein step (b) comprises the following specific procedures: heating the bonded intermediate product obtained from step (a) to 200-350° C. to strip the film and then annealing at 200-350° C. for 20-120 min to get the stripped film.

8. A solid reflection-type bulk acoustic resonator prepared by the preparation method of claim 1.

9. The solid reflection-type bulk acoustic resonator according to claim 8, comprising an upper electrode, a piezoelectric film, a lower electrode, a reflecting layer, a bonding layer and a substrate from top to bottom; or,
an upper electrode, a piezoelectric film, a lower electrode, a bonding layer, a reflecting layer and a substrate from top to bottom.

10. A solid reflection-type bulk acoustic resonator, comprising:
an upper electrode, a piezoelectric film, a lower electrode, a reflecting layer, a bonding layer and a substrate from top to bottom; or,
an upper electrode, a piezoelectric film, a lower electrode, a bonding layer, a reflecting layer and a substrate from top to bottom.

11. The preparation method according to claim 2, wherein the ion-implanted piezoelectric material is obtained by performing ion implantation on a piezoelectric material, wherein an ion implanted is at least one member selected from the group consisting of H ion, He ion, B ion and As ion, an energy of the implanted ion is 100 KeV-1000 KeV, an implantation dose is 2-8×10¹⁶/cm², an ion beam current is 0.1-10 um/cm⁻², an implantation depth is 0.3-8 μm and the substrate is Si, SOI glass, LN or LT.

12. The preparation method according to claim 3, wherein the low acoustic impedance reflecting layer comprises at least one member selected from the group consisting of Al, Ti, SiO₂ and BCB, the high acoustic impedance reflecting layer comprises at least one member selected from the group consisting of Mo, Au, Nb, Ni, Pt, Ta, W, Ir, ZnO, HfO₂, TiO₂, Ta₂O₅ and WO₃, and specific steps for growing reflecting layers are as follows:
(i) growing a low acoustic impedance reflecting layer on one side of the piezoelectric material, then growing a high acoustic impedance reflecting layer on the low acoustic impedance reflecting layer, and repeating for 1-4 cycles; or
(ii) growing a high acoustic impedance reflecting layer on the substrate, then growing a low acoustic impedance reflecting layer on the high acoustic impedance reflecting layer, repeating for 1-3 cycles, and then growing a high acoustic impedance reflecting layer on the low acoustic impedance reflecting layer; or
(iii) growing a low acoustic impedance reflecting layer on one side of the piezoelectric material, then growing a high acoustic impedance reflecting layer on the low acoustic impedance reflecting layer, and repeating for 1-2 cycles, while at the same time, growing a high acoustic impedance reflecting layer above the substrate, then growing a low acoustic impedance reflecting layer on the high acoustic impedance reflecting layer, repeating for 1-2 cycles, and then growing a high acoustic impedance reflecting layer on the low acoustic impedance reflecting layer,
wherein a total thickness of the reflecting layers grown is 200 nm-6000 nm.

13. The preparation method according to claim 4, wherein:
specific steps for polymer bonding are as follows: applying bonding material on one side of the substrate and/or piezoelectric material, wherein the bonding material is organic insulating material which includes at least one member selected from the group consisting of benzocyclobutene and polyimide, and a thickness of the bonding material applied is 100 nm-4000 nm;
specific steps for hydrophilic bonding are as follows: applying bonding material on one side of the substrate and/or piezoelectric material, wherein the bonding material is at least one member selected from the group consisting of silicon oxide, silicon nitride, aluminum oxide and aluminum nitride, and a thickness of the bonding material applied is 100 nm-4000 nm;
specific steps for eutectic bonding are as follows: applying bonding material on one side of the substrate and/or piezoelectric material, wherein the bonding material is at least one member selected from the group consisting of gold, tin and their alloys; and a thickness of the bonding material applied is 100 nm-4000 nm.

14. The preparation method according to claim 5, wherein the lower electrode includes graphical lower electrode and non-graphical lower electrode, the method for growing the graphical lower electrode is as follows: photoetching a pattern to be grown on the surface of the piezoelectric material, then growing an electrode, and then washing off an unwanted part, or, first growing an electrode on the surface of the piezoelectric material, then preparing a mask, and then etching off the unwanted part, wherein the material for growing the lower electrode is Al, Au, Mo, Pt or W and a thickness of the lower electrode is 50-500 nm.

15. The preparation method according to claim 7, wherein a thickness of the piezoelectric material after stripping is 500-1000 nm, the material for growing the upper electrode is Al, Au, Mo, Pt or W, and a thickness of the upper electrode is 50-300 nm.

16. The preparation method according to claim 9, wherein the lower electrode is a graphical lower electrode and an isolating layer is set between the lower electrode and the reflecting layer, and the reflecting layer comprises low acoustic impedance reflecting layers and high acoustic impedance reflecting layers arranged alternately.

17. The preparation method according to claim 10, wherein the lower electrode is a graphical lower electrode and an isolating layer is set between the lower electrode and the reflecting layer, the reflecting layer comprises low acoustic impedance reflecting layers and high acoustic impedance reflecting layers arranged alternately, and the solid reflection-type bulk acoustic resonator is prepared by way of wafer bonding and lay transfer.
